(19) United States
(12) Patent Application Publication
(10) Pub. No.: US 2016/0282690 A1
(43) Pub. Date: Sep. 29, 2016

(54) LIQUID CRYSTAL DISPLAY DEVICE AND RELATED MANUFACTURING METHOD

(71) Applicant: Samsung Display Co., Ltd., Yongin-City (KR)

(72) Inventors: Seok-Joon HONG, Seongnam-si (KR); Sung Hwan WON, Suwon-si (KR); Byung-Gon KUM, Suwon-si (KR); Sang Il PARK, Seoul (KR); Don Chan CHO, Seongnam-si (KR)

(21) Appl. No.: 14/868,118

(22) Filed: Sep. 28, 2015

(30) Foreign Application Priority Data
Mar. 26, 2015 (KR) 10-2015-0042607

(51) Int. Cl. G02F 1/1362; G02F 1/1343; H01L 27/12; G02F 1/1368

(52) U.S. Cl. CPC G02F 1/136286; G02F 1/1368; G02F 1/134336; H01L 27/1262; H01L 27/127; H01L 27/1288; G02F 2001/134318

(57) ABSTRACT

A display device may include the following elements: a switching element comprising a source electrode, a drain electrode, and a gate electrode; a data line electrically connected to the source electrode; a first pixel electrode electrically connected to the drain electrode; a second pixel electrode immediately neighboring the first pixel electrode; a first common electrode and a second common electrode respectively overlapping the first pixel electrode and the second pixel electrode; a first auxiliary common electrode line and a second auxiliary common electrode line each extending parallel to the data line; and a first common electrode line and a second common electrode line respectively electrically connected through the first auxiliary common electrode line and the second auxiliary common electrode line to the first common electrode and the second common electrode.

### CROSS-REFERENCE TO RELATED APPLICATION

This application claims priority to and the benefit of Korean Patent Application No. 10-2015-0042607 filed in the Korean Intellectual Property Office on Mar. 26, 2015; the entire contents of the Korean Patent Application are incorporated herein by reference.

### BACKGROUND

(a) Technical Field

The technical field is related to a liquid crystal display device and a related manufacturing method.

(b) Description of Related Art

A liquid crystal display device may include two panels with field generating electrode, such as a pixel electrode and a common electrode, and may include a liquid crystal layer positioned between the two panels. The liquid crystal display device may apply a voltage to the field generating electrode to generate an electric field for controlling orientations of liquid crystal molecules in the liquid crystal layer, such that transmission of light through the liquid crystal layer may be controlled. As a result, an image may be displayed.

The liquid crystal display device may have a display area and a non-display area. Generally, it is preferable that the display area is maximized and that the non-display area is minimized

The above information disclosed in this Background section is for enhancement of understanding of a background related to the invention. The Background section may contain information that does not form the prior art that is already known in this country to a person of ordinary skill in the art.

### SUMMARY

An embodiment may be related to display device. The display device may include the following elements: a switching element comprising a source electrode, a drain electrode, and a gate electrode; a data line electrically connected to the source electrode; a first pixel electrode electrically connected to the drain electrode; a second pixel electrode immediately neighboring the first pixel electrode; a first common electrode and a second common electrode respectively overlapping the first pixel electrode and the second pixel electrode; a first auxiliary common electrode line and a second auxiliary common electrode line each extending parallel to the data line; and a first common electrode line and a second common electrode line respectively electrically connected through the first auxiliary common electrode line and the second auxiliary common electrode line to the first common electrode and the second common electrode.

The display device may include the following elements: a first liquid crystal material set, which is positioned between the first pixel electrode and the first common electrode; and a second liquid crystal material set, which is positioned between the second pixel electrode and the second common electrode.

The second common electrode line may be positioned between the first common electrode line and a display area of the display device in a plan view of the display device.

The first common electrode line may transmit a first voltage to the first auxiliary common electrode line. The second common electrode line may transmit a second voltage to the second auxiliary common electrode line. The second voltage may be unequal to the first voltage.

The second pixel electrode may be electrically connected to the drain electrode.

At least one of the first auxiliary common electrode line and the second auxiliary common electrode line may overlap both the first pixel electrode and the second pixel electrode.

Both the first auxiliary common electrode line and the second auxiliary common electrode line may overlap both the first pixel electrode and the second pixel electrode.

Exactly one the first auxiliary common electrode line and the second auxiliary common electrode line may overlap both the first pixel electrode and the second pixel electrode.

The first auxiliary common electrode line and the second auxiliary common electrode line may be formed of a same material as the data line.

The display device may include an insulating layer. A surface of the insulating layer may directly contact each of the first auxiliary common electrode line, the second auxiliary common electrode line, and the data line.

The display device may include a third pixel electrode. The third pixel electrode may overlap the second common electrode and may be insulated from the second pixel electrode. At least one of the first auxiliary common electrode line and the second auxiliary common electrode line may overlap all of the first pixel electrode, the second pixel electrode, and the third pixel electrode. The display device may include a third common electrode, which may be electrically connected through the first auxiliary common electrode line to the first common electrode line. The second common electrode may be positioned between the third common electrode and the first common electrode in a plan view of the display device. The display device may include a fourth pixel electrode, which may overlap the third common electrode. The second common electrode may immediately neighbor each of the third common electrode and the first common electrode. The fourth pixel electrode may be electrically connected to the third pixel electrode.

The display device may include a gate line electrically connected to the gate electrode. The gate line may extend substantially parallel to at least one of the first common electrode line and the second common electrode line. The gate line may be formed of a same material as at least one of the first common electrode line and the second common electrode line. The display device may include a substrate. A surface of the substrate may directly contact each of the gate line, the first common electrode line and the second common electrode line.

The display device may include a first bridge electrode. The first auxiliary common electrode line may be electrically connected through the first bridge electrode to the first common electrode. The first bridge electrode may be formed of a same material as the first pixel electrode. A first portion of the first bridge electrode may directly contact the first auxiliary common electrode line. A second portion of the first bridge electrode may extend at an angle with respect to the first portion of the first bridge electrode in a plan view of the display device, may overlap the data line, and may directly contact the first common electrode.

A liquid crystal display according to an embodiment may include the following elements: a substrate including a display area and a non-display area; a gate line positioned on the substrate; a first common electrode line and a second common electrode line positioned in the non-display area and extending parallel to the gate line; a data line crossing the gate line; a first auxiliary common electrode line extending parallel to the data line and electrically connected to the first common electrode line; a second auxiliary common electrode line extending parallel to the data line and electrically connected to the second common electrode line; first-type common electrodes electrically connected to the first auxiliary common electrode line; and second-type common electrodes electrically connected to the second auxiliary common electrode line.

The first common electrode line and the second common electrode line may be applied with different voltages.

A pixel electrode may overlap at least one of the first auxiliary common electrode line and the second auxiliary common electrode line.

The first auxiliary common electrode line and the second auxiliary common electrode line may be formed of the same material as the data line.

The first-type common electrodes and the second-type common electrode may extend parallel to the first common electrode line and may be alternately arranged.

The first auxiliary common electrode line and the second auxiliary common electrode line may both be formed in a same pixel column.

The first auxiliary common electrode line and the first common electrode may be electrically connected to each other through a first bridge electrode formed of the same material as the pixel electrode. The second auxiliary common electrode line and the second common electrode may be electrically connected to each other through a second bridge electrode formed of the same material as the pixel electrode.

Exactly one of the first auxiliary common electrode line and the second auxiliary common electrode line may be formed in a pixel column.

The first-type common electrodes and the second-type common electrodes may extend parallel to the data line and may be alternately arranged.

A manufacturing method of a liquid crystal display according to an embodiment may include the following steps: forming a gate line, a first common electrode line, and a second common electrode line on a substrate; forming a semiconductor layer on the substrate; forming a data line crossing the gate line; forming a first auxiliary common electrode line parallel to the data line and connected to the first common electrode line; forming a second auxiliary common electrode line connected to the second common electrode line; forming an insulating layer on the gate line, the first common electrode line, the second common electrode line, the semiconductor layer, the first auxiliary common electrode line, the second auxiliary common electrode line, and the data line; forming a pixel electrode on the insulating layer; forming a sacrificial layer on the pixel electrode; forming a first-type common electrode and a second-type common electrode on the sacrificial layer; forming a roof layer on the common electrode; removing the sacrificial layer to form a microcavity that has an injection hole; injecting a liquid crystal material into the microcavity; and forming an overcoat on the roof layer, the overcoat covering the injection hole.

In the step of forming the first-type common electrode and the second-type common electrode, a plurality of first-type common electrodes and a plurality of second-type common electrodes may be formed, and the first-type common electrodes and the second-type common electrodes may be alternately arranged.

The method may further include forming a first bridge electrode that is electrically connected to the first auxiliary common electrode line and forming a second bridge electrode that is electrically connected to the second auxiliary common electrode line while forming the pixel electrode. The first-type common electrode may be electrically connected to the first auxiliary common electrode line through the first bridge electrode. The second common electrode may be electrically connected to the second auxiliary common electrode line through the second bridge electrode.

According to embodiments, common electrode lines of a liquid crystal display device may be substantially thin, such that the non-display area of the display device may be advantageously minimized. According to embodiments, different common electrodes in a same pixel may be applied with different voltages, such that visibility of an image displayed by a liquid crystal display device may be optimized.

### BRIEF DESCRIPTION OF THE DRAWINGS

FIG. 1 is a schematic (top) plan view illustrating a liquid crystal display device, or liquid crystal display (for conciseness), according to an embodiment.

FIG. 2 is a schematic (top) plan view illustrating a pixel of a liquid crystal display according to an embodiment.

FIG. 3 is a schematic (top) plan view illustrating a portion A of a liquid crystal display indicated in FIG. 1 according to an embodiment.

FIG. 4 is a schematic cross-sectional view of a liquid crystal display taken along a line IV-IV indicated in FIG. 2 according to an embodiment.

FIG. 5 is a schematic cross-sectional view of a liquid crystal display taken along a line V-V indicated in FIG. 2 according to an embodiment.

FIG. 6 is a schematic (top) plan view illustrating a pixel of a liquid crystal display according to an embodiment.

FIG. 7 is a schematic (top) plan view illustrating a portion A indicated in FIG. 1 according to an embodiment.

### DETAILED DESCRIPTION OF THE EMBODIMENTS

Some embodiments are described with reference to the accompanying drawings. The described embodiments may be modified in various ways.

Although the terms “first”, “second”, etc. may be used herein to describe various elements, these elements should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used to differentiate different categories or sets of elements. For conciseness, the terms “first”, “second”, etc. may represent, for example, “first-category (or first-set)”, “second-category (or second-set)”, etc., respectively.

When a first element (such as a layer, film, region, or substrate) is referred to as being “on” a second element, the first element can be directly on the second element, or one or more intervening elements may also be present. When a first element is referred to as being “directly on” a second element, there are no intended intervening elements provided between the first element and the second element.

Same reference numbers may be used to refer to identical elements and/or analogous elements. Unless explicitly described to the contrary, the word “comprise” and variations, such as “comprises” or “comprising”, imply inclusion of stated elements but not exclusion of other elements.

The term “connect” may mean “electrically connect”. The term “insulate” may mean “electrically insulate”. The term “formed” may mean “formed, provided, and/or positioned”.

In the drawings, thicknesses of layers, films, panels, regions, etc., may be exaggerated for clarity. A drawing and related description may use a particular position and/or orientation of a device as an example. The device may have various positions and/or orientations.

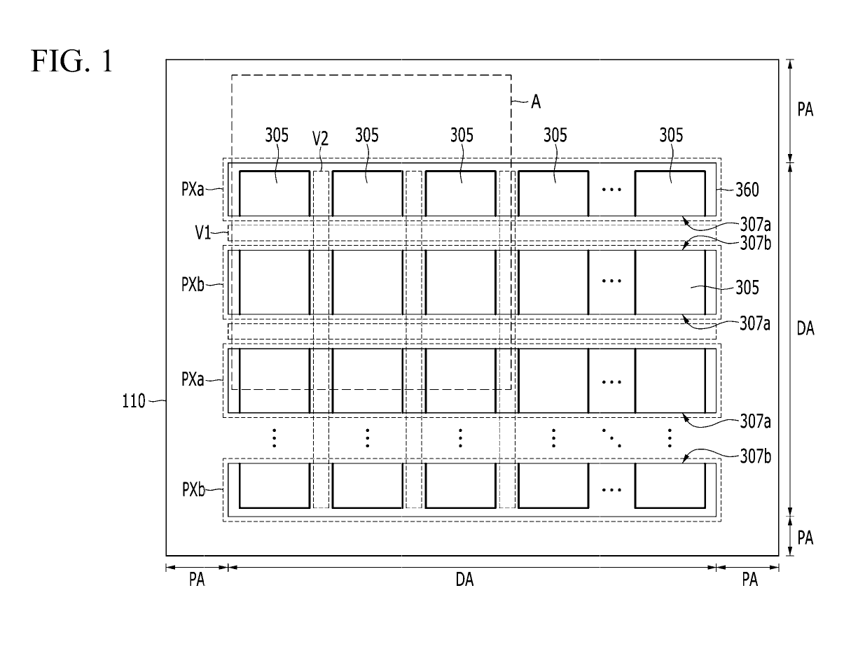

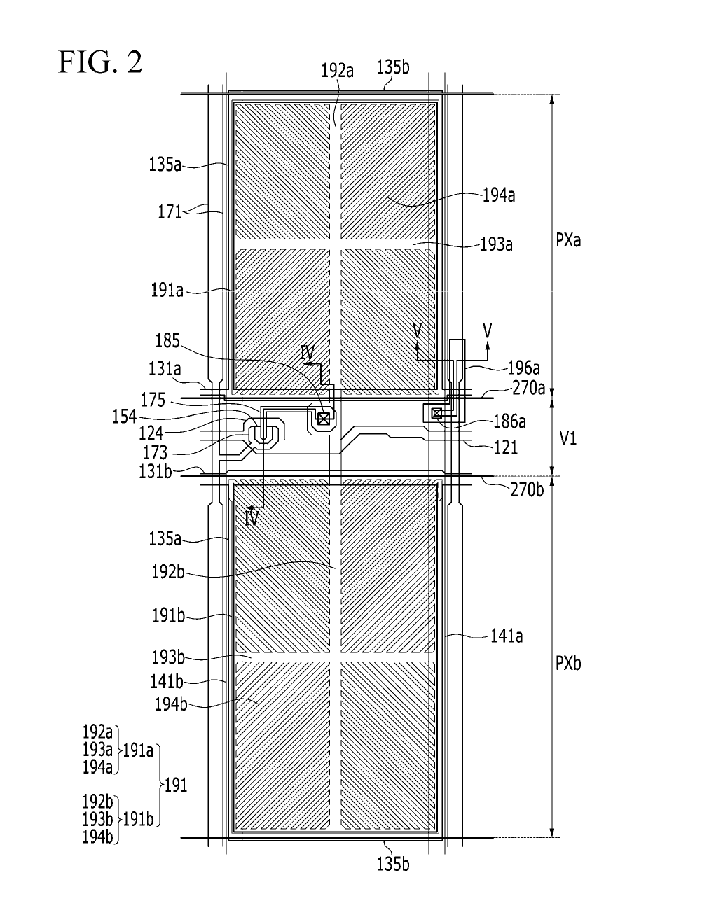

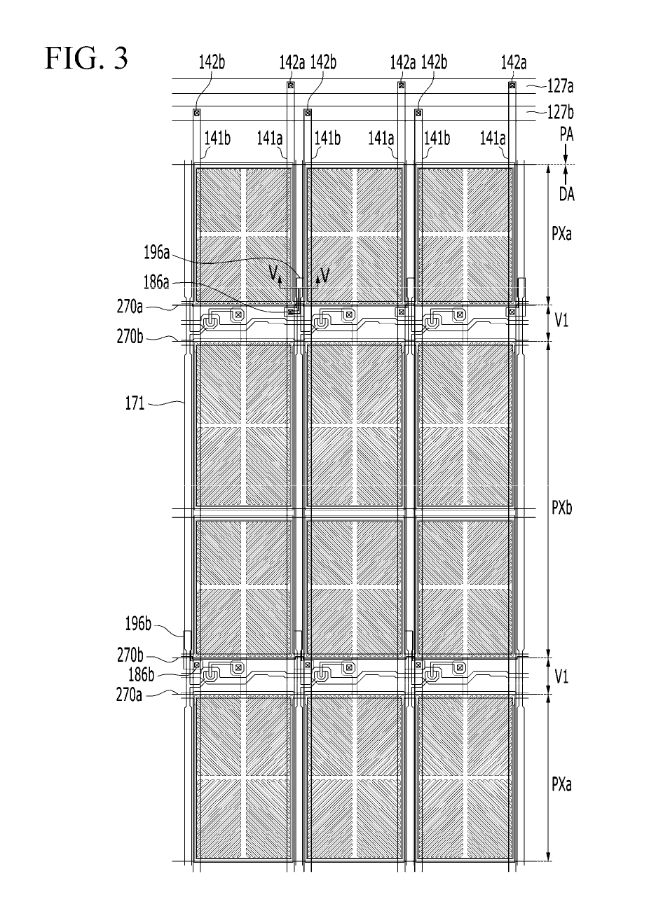

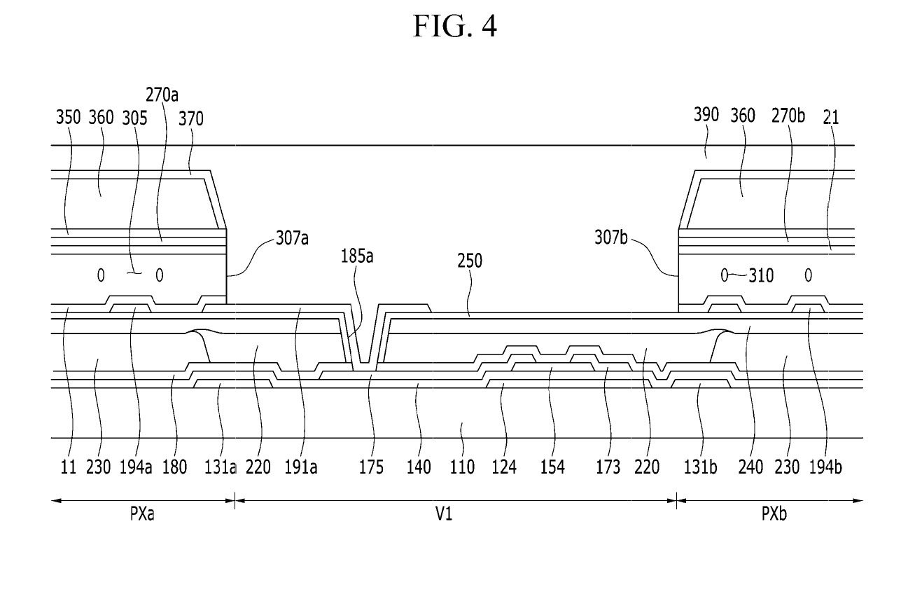

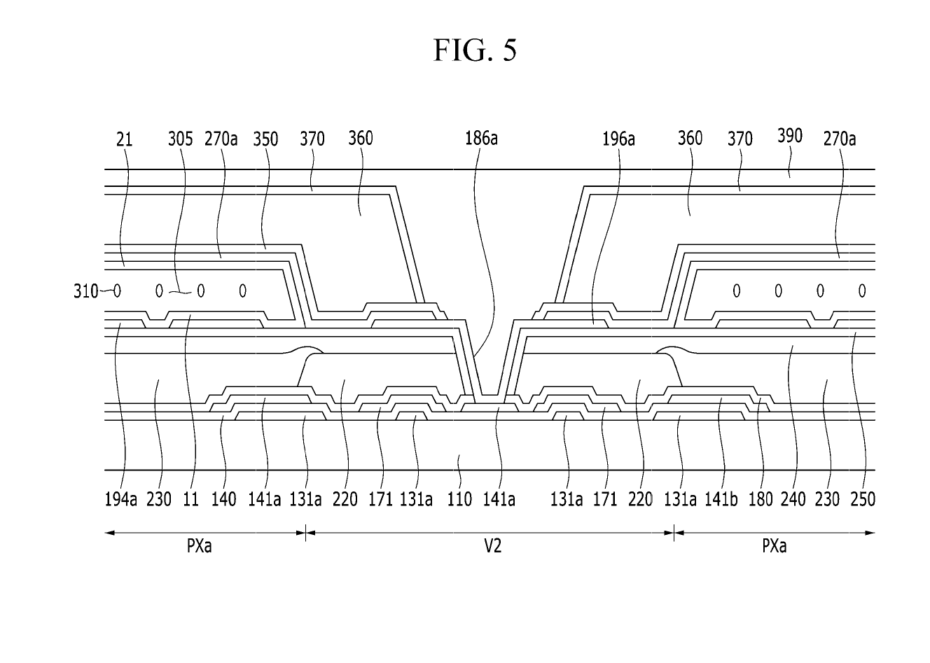

FIG. 1 is a schematic (top) plan view illustrating a liquid crystal display device, or liquid crystal display (for conciseness), according to an embodiment. FIG. 2 is a schematic (top) plan view illustrating a pixel of the liquid crystal display according to an embodiment. FIG. 3 is a schematic (top) plan view illustrating a portion A of the liquid crystal display indicated in FIG. 1 according to an embodiment. FIG. 4 is a schematic cross-sectional view taken along a line IV-IV indicated in FIG. 2 according to an embodiment. FIG. 5 is a schematic cross-sectional view taken along a line V-V indicated in FIG. 2 according to an embodiment.

The liquid crystal display includes a display area DA and a non-display area PA. The non-display area PA may abut and/or surround the display area DA.

The display area DA is configured to display images. The non-display area PA may accommodate one or more of a gate driver, a data driver, a gate pad, and a data pad, which may be connected to an external circuit. The gate pad is a wide portion positioned at an end of a gate line, and the data pad is a wide portion positioned at an end of a data line.

The display area DA may include a plurality of pixel areas including, which may include first-type pixel areas (or first pixel areas) and second-type pixel areas (or second pixel areas). For improving visibility of displayed images, an electric field at a first pixel area may be different from an electric field at a second pixel area. Each first-type pixel row PXa (or first pixel row PXa) may include a plurality of first pixel areas. Each second-type pixel row PXb (or second pixel row PXb) may include a plurality of second pixel areas.

A plurality of microcavities 305 may be formed in the display area DA of the liquid crystal display. Each microcavity 305 may correspond to a first pixel area or a second pixel area. The microcavities 305 may contain liquid crystal material sets, thereby forming a liquid crystal layer. The microcavities 305 are covered by roof layers 360, which may extend the row direction. The roof layers 360 may be mainly positioned in the display area DA. Trenches V1) may be positioned between roof layers 360 in a plan view of the liquid crystal display.

The microcavities 305 may receive the liquid crystal material sets through the trenches V1, first-type injection holes 307a (or first injection holes 307a), and second-type injection holes 307b (or second injection holes 307b). A first injection hole 307a and a second injection hole 307b respectively expose a microcavity 305 positioned in a first pixel row PXa and a microcavity 305 positioned in a second pixel row PXb. Partitions V2 may extend in the column direction and may be positioned between microcavities 305.

In an embodiment, a microcavity 305 may cover a plurality of pixel areas, and a pixel row (e.g., PXa or PXb) may have only one microcavity 305 (i.e., one liquid crystal material set). In an embodiment, microcavities 305 (or liquid crystal material sets) in a pixel row (e.g., PXa or PXb) may be connected to each other (without being separated by partitions V2).

The liquid crystal display may include a substrate 110, which may be formed of, for example, glass or plastic. A gate line 121 and a gate electrode 124 that protrude from (and/or connected to) the gate line 121 are formed on the substrate 110. The gate line 121 mainly extends in a horizontal direction (parallel to the pixel rows PXa) and may transmit a gate signal. In a plan view of the liquid crystal display, the gate line 121 is positioned between two microcavities 305 that are immediately adjacent to each other in the column direction. That is, the gate line 121 is positioned in the trench V1 between two immediately neighboring pixel rows in the plan view of the liquid crystal display. The gate electrode 124 is a component of a switching element of the liquid crystal display and protrudes from the gate line 121 in the column direction. The gate electrode 124 is connected to the gate line 121 for receiving the gate signal. The gate electrode 124 may have various configurations and/or various shapes according to various embodiments.

Storage electrode lines 131a and 131b and storage electrodes 135a and 135b protruding from (and/or connected to) the storage electrode lines 131a and 131b may be formed on the substrate 110. The storage electrode lines 131a and 131b include a first storage electrode line 131a and a second storage electrode line 131b. The storage electrodes 135a and 135b include longitudinal portions 135a vertically extending from the storage electrode lines 131a and 131b and include transverse portions 135b connecting ends of a pair of longitudinal portions 135a to each other. A predetermined voltage may be applied to the storage electrode lines 131a and 131b. In an embodiment, the voltage applied the first storage electrode line 131a may be unequal to the voltage applied to the second storage electrode line 131b. The storage electrodes 135a and 135b may surround portions of the pixel electrode 191 in a plan view of the liquid crystal display.

In an embodiment, auxiliary common electrode lines 141a and 141b may be separated (and insulated) from the storage electrode lines 131a and 131b. In an embodiment, the storage electrode lines 131a and 131b may be connected to the auxiliary common electrode lines 141a and 141b.

In the non-display area PA, a first common electrode line 127a and a second common electrode line 127b may extend parallel to the pixel rows PXa and PXb (in the same direction as the gate line 121). The first common electrode line 127a and the second common electrode line 127b may be positioned at a same side (e.g., the upper side) with respect to the display area DA in a plan view of the liquid crystal display. The first common electrode line 127a and the second common electrode line 127b are positioned at the same layer as the gate line 121. The first common electrode line 127a and the second common electrode line 127b are respectively connected to first-type auxiliary common electrode lines 141a (or first auxiliary common electrode lines 141a) and second-type auxiliary common electrode lines 141b (or second auxiliary common electrode lines 141b). A gate insulating layer 140 is formed on the first common electrode line 127a, the second common electrode line 127b, and the gate line 121. The first auxiliary common electrode line 141a and the second auxiliary common electrode line 141b are formed on the gate insulating layer 140. The gate insulating layer 140 has a fourth-type contact hole 142a (or fourth contact hole 142a) exposing a part of the first common electrode line 127a and has a fifth-type contact hole 142b (or fifth contact hole 142b) exposing a part of the second common electrode line 127b. The first common electrode line 127a is connected to the first auxiliary common electrode line 141a through the fourth contact hole 142a. The second common electrode line 127b is connected to the second auxiliary common electrode line 141b through the fifth contact hole 142b. The first common electrode line 127a and the second common electrode line 127b are formed at only one side with respect to the display area DA. No common electrode lines may be required at the right side or the left side of the liquid crystal display. Advantageous, the non-display area PA may be minimized, such that the size the liquid crystal display may be minimized

The gate insulating layer 140 is formed on the gate line 121, the gate electrode 124, the storage electrode lines 131a and 131b, the storage electrodes 135a and 135b, the first common electrode line 127a, and the second common electrode line 127b. The gate insulating layer 140 may be formed of an inorganic insulating material, such as silicon nitride (SiNx) and/or silicon oxide (SiOx). The gate insulating layer 140 may have a single-layer structure or a multilayer structure. The gate insulating layer 140 has the fourth contact hole 142a exposing the part of the first common electrode line 127a and has the fifth contact hole 142b exposing the part of the second common electrode line 127b.

A semiconductor layer 154 is formed on the gate insulating layer 140. The semiconductor layer 154 is positioned on the gate electrode 124. The semiconductor layer 154 may be made of amorphous silicon, polycrystalline silicon, or a metal oxide.

An ohmic contact (not shown) may be formed on the semiconductor layer 154. The ohmic contact may be made of for example, n+ hydrogenated amorphous silicon in which silicide or an n-type impurity is doped at a high concentration.

A data line 171, a source electrode 173, a drain electrode 175, the first auxiliary common electrode line 141a, and the second auxiliary common electrode line 141b are formed on the semiconductor layer 154 and the gate insulating layer 140.

The semiconductor layer 154 may overlap the gate electrode 124 and may be connected to the data line 171.

The data line 171 may transmit a data signal and may mainly extend in a vertical direction perpendicular to the pixel rows PXa and PXb. The data line 171 may cross the gate line 121 and the storage electrode lines 131a and 131b in a plan view of the liquid crystal display. In the plan view, the data line 171 is positioned between two microcavities 305 immediately adjacent to each other in a row direction. That is, the data line 171 overlaps a partition V2.

The source electrode 173 extends from the data line 171 and overlaps the gate electrode 124. The source electrode 173 may have a C-shaped structure. The source electrode 173 is a component of the switching element that includes the gate electrode 124.

The drain electrode 175 is separated from the source electrode 173 and overlaps the gate electrode 124. The drain electrode 175 is a component of the switching element that includes the gate electrode 124 and the source electrode 173. A channel is formed in the semiconductor layer 154 at a portion positioned between two portions of the semiconductor layer 154 that respectively overlap the source electrode 173 and the drain electrode 175. The gate electrode 124, the semiconductor layer 154, the source electrode 173, and the drain electrode 175 form a switching element (e.g., a transistor).

The first auxiliary common electrode lines 141a and the second auxiliary common electrode lines 141b extend parallel to the data lines 171 and are separated (and insulated) from the data line 171. In an embodiment, a data line 171 may be positioned between a first auxiliary common electrode line 141a and an immediately neighboring second auxiliary common electrode line 141b in a plan view of the liquid crystal display. The first auxiliary common electrode line 141a is connected to the first common electrode line 127a through a fourth contact hole 142a to receive a first common voltage, and the second auxiliary common electrode line 141b is connected to the second common electrode line 127b through a fifth contact hole 142b to receive a second voltage.

A passivation layer 180 is formed on the data line 171, the source electrode 173, the drain electrode 175, and the auxiliary common electrode lines 141a and 141b. The passivation layer 180 may be made of an organic or inorganic insulating material. The passivation layer 180 may have a single-layer structure or a multilayer structure.

Color filters 230 may be formed on the passivation layer 180. In an embodiment, the passivation layer 180 may be omitted. Each color filter may overlap a pixel electrode 191. Each color filter 230 may display one of primary colors such as one of red, green, blue, cyan, magenta, yellow, and white. The color filter 230 may not overlap the trenches V1 or the partitions V2.

A light blocking member 220 is formed between the adjacent color filters 230. The light blocking member 220 may be a black matrix formed at boundaries of pixel areas and on switching elements to prevent light leakage. The light blocking member 220 may overlap the trenches V1 and the partitions V2. The color filter 230 and the light blocking member 220 may partially overlap each other.

A first insulating layer 240 may be formed on the color filter 230 and the light blocking member 220. The first insulating layer 240 may be made of an organic or inorganic insulating material and may provide a flat surface on the color filters 230 and the light blocking member 220.

A second insulating layer 250 may be formed on the first insulating layer 240. The second insulating layer 250 may be made of the inorganic insulating material and may protect the color filters 230 and the first insulating layer 240.

The passivation layer 180, the light blocking member 220, the first insulating layer 240, and the second insulating layer 250 have a first-type contact hole 185a (or first contact hole 185a) exposing a part of the drain electrode 175, have a second-type contact hole 185 (or second contact hole 186a) exposing a part of the first auxiliary common electrode line 141a, and have a third-type contact hole 186b (or third contact hole 186b) exposing a part of the second auxiliary common electrode line 141b are formed. Referring to FIG. 3, in the plan view, the second contact hole 186a is formed at a trench V1 between a first pixel row PXa and a second pixel row PXb, and the third contact hole 186b is formed at another trench V1 between the second pixel row PXb and another first pixel row PXa.

A pixel electrode 191, a first-type bridge electrode 196a (or first bridge electrode 196a), and a second-type bridge electrode 196b (or second bridge electrode 196b) are formed on the second insulating layer 250. The pixel electrode 191, the first bridge electrode 196a, and the second bridge electrode 196b may be made of a transparent metal material, such as indium tin oxide (ITO) and/or indium zinc oxide (IZO).

The pixel electrode 191 includes a first pixel electrode 191a and a second pixel electrode 191b electrically connected to each other. The first pixel electrode 191a and the second pixel electrode 191b are disposed at two opposite sides with respect to a gate line 121 (and with respect to a trench V1) in a pixel column direction.

The first pixel electrode 191a and the second pixel electrode 191b are immediately adjacent to each other in the column direction, have generally quadrangle shapes, and include cross-type stem portions formed of horizontal stem portions 193a and 193b and vertical stem portions 192a and 192b crossing the horizontal stem portions 193a and 193b. The first pixel electrode 191a and the second pixel electrode 191b include a plurality of minute branches 194a and 194b. The pixel electrode 191 is divided into eight sub-regions by the horizontal stem portions 193a and 193b and the vertical stem portions 192a and 192b. The minute branch portions 194a and 194b obliquely extend from the horizontal stem portions 193a and 193b and the vertical stem portions 192a and 192b at an angle of approximately 45° or 135° with respect to the gate lines 121 and/or the horizontal stem portions 193a and 193b. Fine branch portions 194a or 194b of two immediate adjacent sub-regions may be orthogonal to each other. The vertical stem portions 192a and 192b may be directly and/or electrically connected to each other and may be electrically connected to the drain electrode 175.

The first pixel electrode 191a is connected to the drain electrode 175 through the first contact hole 185. The second pixel electrode 191b may be connected to the first pixel electrode 191a such that the first pixel electrode 191a and the second pixel electrode 191b may receive the same data voltage from the drain electrode 175. An electric field may be formed between the pixel electrode 191 and each of common electrodes 270a and 270b.

A first bridge electrode 196a may connect the first auxiliary common electrode line 141a to the first common electrode 270a and may overlap the upper portion of the first auxiliary common electrode line 141a. The first bridge electrode 196a is connected to the first auxiliary common electrode line 141a through the second contact hole 186a, which exposes the upper portion of the first auxiliary common electrode line 141a. The first bridge electrode 196a may directly contact the first common electrode 270a and/or the first auxiliary common electrode line 141a. In an embodiment, the first bridge electrode 196a may have a mirrored-L-shape. A first portion of the first bridge electrode 196a may extend parallel to and overlap a trench V1, may extend perpendicular to the first auxiliary common electrode line 141a in the plan view, and may directly contact the first auxiliary common electrode line 141a. A second portion of the first bridge electrode 196a may extend parallel to and overlap a partition V2, may extend parallel to the first auxiliary common electrode line 141a in the plan view, may directly contact the first common electrode 270a, and may be connected through the first portion of the first bridge electrode 196a to the first auxiliary common electrode line 141a. The first bridge electrode 196a may have other shapes according to other embodiments. In an embodiment, the first auxiliary common electrode line 141a and the first common electrode 270a may directly contact and connect to each other through the contact hole 186a, and the first bridge electrode 196a may be omitted.

A second bridge electrode 196b may connect the second auxiliary common electrode line 141b to the second common electrode 270b and may overlap the upper portion of the second auxiliary common electrode line 141b. The second bridge electrode 196b is connected to the second auxiliary common electrode line 141b through the third contact hole 186b, which exposes the second auxiliary common electrode line 141b. The second auxiliary common electrode line 141b and/or the second common electrode 270b may directly contact the second bridge electrode 196b. In an embodiment, the second bridge electrode 196b may have an L-shape in a plan view of the liquid crystal display. A first portion of the second bridge electrode 196b may extend parallel to and overlap a trench V1, may extend perpendicular to the second auxiliary common electrode line 141b in the plan view, and may directly contact the second auxiliary common electrode line 141b. A second portion of the second bridge electrode 196b may extend parallel to and overlap a partition V2, may extend parallel to the second auxiliary common electrode line 141b in the plan view, may directly contact the second common electrode 270b, and may be connected through the first portion of the second bridge electrode 196b to the second auxiliary common electrode line 141b. The second bridge electrode 196b may have other shapes according to other embodiments. In an embodiment, the second auxiliary common electrode line 141b and the second common electrode 270b may directly contact and connect to each other through the contact hole 186b, and the second bridge electrode 196b may be omitted.

The first common electrode 270a and the second common electrode 270b may be separated by a predetermined distance from the pixel electrode 191 and may overlap the pixel electrode 191. A microcavity 305 and the associated liquid crystal material set are formed between the pixel electrode 191 and each of the common electrodes 270a and 270b. A microcavity 305 may be enclosed by the pixel electrode 191 and each of the common electrodes 270a and 270b. The common electrodes 270a and 270b may extend in the pixel row direction and may not substantially overlap any trenches V1 in a direction perpendicular to the substrate 110. First common electrodes 270a and second common electrodes 270b may be alternately arranged along the pixel column direction and may be separated by trenches V1 in a plan view of the liquid crystal display. Each first common electrode 270a may be formed in (and/or overlap) a first pixel row PXa. Each second common electrode 270b may be formed in (and/or overlap) a second pixel row PXb. The common electrodes 270a and 270b may cover upper surfaces and side surfaces of microcavities 305 (and partitions V2). Widths and/or areas of the microcavities 305 may be configured according to a size and/or a resolution of the liquid crystal display device. Portions of the common electrodes 270a and 270b may directly contact the second insulating layer 250 and may be positioned between two immediately neighboring pixel rows PXa or PXb in a plan view of the liquid crystal display.

The common electrodes 270a and 270b may be formed of a transparent metal material, such as ITO and/or IZO.

The first common electrode 270a is connected to the first auxiliary common electrode line 141a through the first bridge electrode 196a, and the second common electrode 270b is connected to the second auxiliary common electrode line 141b through the second bridge electrode 196b.

A first common voltage is applied to the first common electrode 270a through the first auxiliary common electrode line 141a. A second common voltage is applied to the second common electrode 270b through the second auxiliary common electrode line 141b. Therefore, a first electric field may be formed between the pixel electrode 191 and the first common electrode 270a, and a second electric field may be formed between the pixel electrode 191 and the second common electrode 270b. In an embodiment, the first common voltage may be unequal to the second common voltage. Accordingly, two different electric fields may be implemented in one pixel. Advantageously, visibility of a displayed image may be optimized.

A first alignment layer 11 is formed on the pixel electrode 191. The first alignment layer 11 may be formed directly on a portion of the second insulating layer 250 that is not covered by the pixel electrode 191. A second alignment layer 21 is formed on each of the common electrodes 270a and 270b and may face the first alignment layer 11. The first alignment layer 11 and the second alignment layer 21 may be vertical alignment layers and may be formed of an alignment material, such as polyamic acid, polysiloxane, and/or polyimide. Alignment layers 11 and 21 may be connected at a side wall or an edge of a microcavity 305.

A liquid crystal material set including liquid crystal molecules 310 is formed in each microcavity 305. The liquid crystal molecules 310 have negative dielectric anisotropy and may be oriented in a vertical direction perpendicular to the substrate 110 when no electric field is applied. That is, vertical alignment may be implemented.

The first pixel electrode 191a and the second pixel electrode 191b, to which the data voltage is applied, generate electric fields together with the common electrodes 270a and 270b to determine directions of the liquid crystal molecules 310. Light passing through the liquid crystal layer (which includes the liquid crystal material sets) is determined by the direction of the liquid crystal molecules 310. Therefore, a desired image may be displayed.

A third insulating layer 350 may be formed on the common electrode 270a and 270b. The third insulating layer 350 may be formed of an inorganic insulating material, such as a silicon nitride (SiNx) and/or a silicon oxide (SiOx), and may be omitted in some embodiments.

Roof layers 360 are formed on the third insulating layer 350. The roof layers 360 may be formed of an organic material. The roof layers 360 may extend in the row direction and may cover upper surfaces and sides of the microcavities 305 (and the partitions V2). A roof layer 360 may be positioned at a predetermined height from the corresponding pixel electrode 191 and may be hardened through a hardening process to maintain the shape of the corresponding microcavity 305.

Common electrodes 270a and 270b and roof layers 360 may expose sides of microcavities 305 with injection holes 307a and 307b. An aligning agent and a liquid crystal material may be injected through the injection holes 307a and 307b into the microcavities 305.

A fourth insulating layer 370 may be formed on each roof layer 360. The fourth insulating layer 370 may be formed of an inorganic insulating material, such as silicon nitride (SiNx) and/or silicon oxide (SiOx). The fourth insulating layer 370 may cover the upper surface and sides of the roof layer 360. The fourth insulating layer 370 serves to protect the roof layer 360 and may be omitted in some embodiments.

An overcoat 390 is formed on the fourth insulating layer 370. The overcoat 390 may cover the injection holes 307a and 307b. That is, the overcoat 390 may seal the microcavities 305 to prevent leakage of the liquid crystal molecules 310. The overcoat 390 may be made of a material that does not substantially react with the liquid crystal molecules 310. For example, the overcoat 390 may be made of parylene and/or another suitable material. The overcoat 390 may provide a flat surface on the roof layers 360, the trenches V1, and the partitions V2. The overcoat 390 may have a multilayer structure, such as a double-layer structure or a triple-layer structure. In the overcoat 390, materials of immediately adjacent layers are different from each other. For example, the overcoat 390 may include a layer made of an organic insulating material and a layer made of an inorganic insulating material.

Although not illustrated, polarizers may be formed on the upper and lower sides of the liquid crystal display. The polarizers may include a first polarizer and a second polarizer. The first polarizer may be attached onto the lower side of the substrate 110, and the second polarizer may be attached onto the overcoat 390.

A manufacturing method of the liquid crystal display is described with reference to FIG. 1 to FIG. 5.

On the substrate 110, after the gate line 121, the first common electrode line 127a, and the second common electrode line 127b (which extend in the horizontal direction) have been formed, the gate insulating layer 140 and the semiconductor layer 154 are sequentially provided (e.g., deposited). The data line 171, the source electrode 173, the drain electrode 175, and the first auxiliary common electrode line 141a and the second auxiliary common electrode line 141b (which extend substantially parallel to the data line 171 in the vertical direction) are formed.

The gate line 121, the storage electrode line 131a and 131b, the first common electrode line 127a, and the second common electrode line 127b are formed on the substrate 110. The gate line 121, the storage electrode line 131a and 131b, the first common electrode line 127a, and the second common electrode line 127b are formed with the same material layer and may be made of a metal material, such as aluminum and/or copper. In an embodiment, the first common electrode line 127a, the second common electrode line 127b, and the gate line 121 extend substantially parallel to each other in the same horizontal direction.

The gate insulating layer 140 may cover the gate line 121, the storage electrode lines 131a and 131b, the first common electrode line 127a, and the second common electrode line 127b. The fourth contact hole 142a and the fifth contact hole 142b are formed in the gate insulating layer 140 for enabling connection between the first common electrode line 127a and the first auxiliary common electrode line 141a and connection between the second common electrode line 127b and the second auxiliary common electrode line 141b.

The semiconductor layer 154, the data line 171, the source electrode 173, the drain electrode 175, the first auxiliary common electrode line 141a, and the second auxiliary common electrode line 141b are formed on the gate insulating layer 140. The first auxiliary common electrode line 141a, the second auxiliary common electrode line 141b, and the data line 171 are formed in the same vertical direction. In an embodiment, the first auxiliary common electrode line 141a is connected to the first common electrode line 127a through the fourth contact hole 142a, and the second auxiliary common electrode line 141b is connected to the second common electrode line 127b through the fifth contact hole 142b.

The passivation layer 180, the color filter 230, the light blocking member 220, the first insulating layer 240, and the second insulating layer 250 are sequentially provided (e.g., deposited) on one or more of the data line 171, the source electrode 173, the drain electrode 175, the first auxiliary common electrode line 141a, and the second auxiliary common electrode line 141b.

In one or more of the passivation layer 180, the light blocking member 220, the first insulating layer 240, and the second insulating layer 250, the first contact hole 185 (for exposing the part of the drain electrode 175), the second contact hole 186a (for exposing a part of the first auxiliary common electrode line 141a), and the third contact hole 186b (for exposing a part of the second auxiliary common electrode line 141b) are formed.

The pixel electrode 191, the first bridge electrode 196a, and the second bridge electrode 196b are formed on the second insulating layer 250. A sacrificial layer made of a photoresist is formed on the pixel electrode 191. The sacrificial layer is patterned to form the trenches V1 and spaces for the partitions V2.

The common electrodes 270a and 270b are provided (e.g., deposited) on the sacrificial layer. A material layer provided for forming the common electrodes 270a and 270b may be patterned to remove portions corresponding to the trenches V1, thereby forming the first common electrode 270a and the second common electrode 270b. The first common electrode 270a is connected to the first auxiliary common electrode line 141a through the first bridge electrode 196a, and the second common electrode 270b is connected to the second auxiliary common electrode line 141b through the second bridge electrode 196b.

Subsequently, the third insulating layer 350, the roof layers 360, and the fourth insulating layer 370 are sequentially formed on the common electrodes 270a and 270b.

The third insulating layer 350, the roof layers 360, and the fourth insulating layer 370 may be formed on the sacrificial layer, may fill the partitions V2, and may expose the scarification layer at the trenches V1. In an embodiment, the third insulating layer 350, the roof layers 360, and the fourth insulating layer 370 may partially remain in the trenches V1.

The sacrificial layer is removed through the trench V1 through an O₂ ashing treatment.

After the removal of the sacrificial layer, microcavities 305 having injection holes 307a and 307b are formed at opposite sides of trenches V1.

An alignment material is injected through a first injection hole 307a and a second injection hole 307b to form the alignment layers 11 and 21 on a pixel electrode 191 and common electrodes 270a and 270b.

Subsequently, liquid crystal material sets containing liquid crystal molecule 310 are injected into microcavities 305 through the first injection hole 307a and the second injection hole 307b using capillary forces. The sizes of the liquid crystal injection holes 307a and 307b may be reduced after the alignment layers 11 and 21 have been formed.

Subsequently, the overcoat 390 is formed to cover the liquid crystal injection holes 307a and 307b. The overcoat 390 may seal the microcavities 305 to prevent leakage of liquid crystal molecules 310. The overcoat 390 may provide a flat (or planarized) surface on the roof layers 360, the trenches V1, and the partitions V2. The overcoat 390 may have a multilayer structure. The overcoat 390 may be formed of a thermosetting resin, silicon oxycarbide (SiOC), and/or graphene.

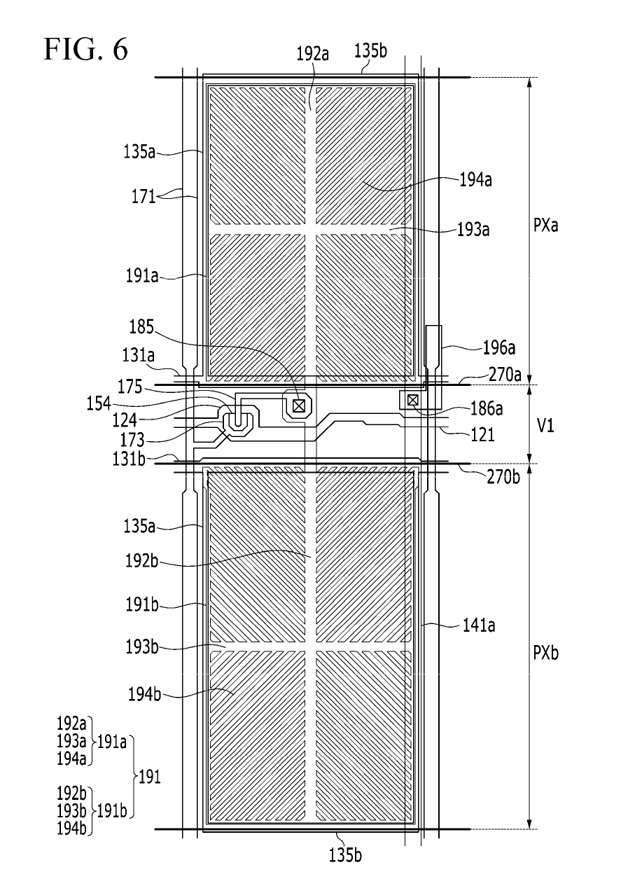

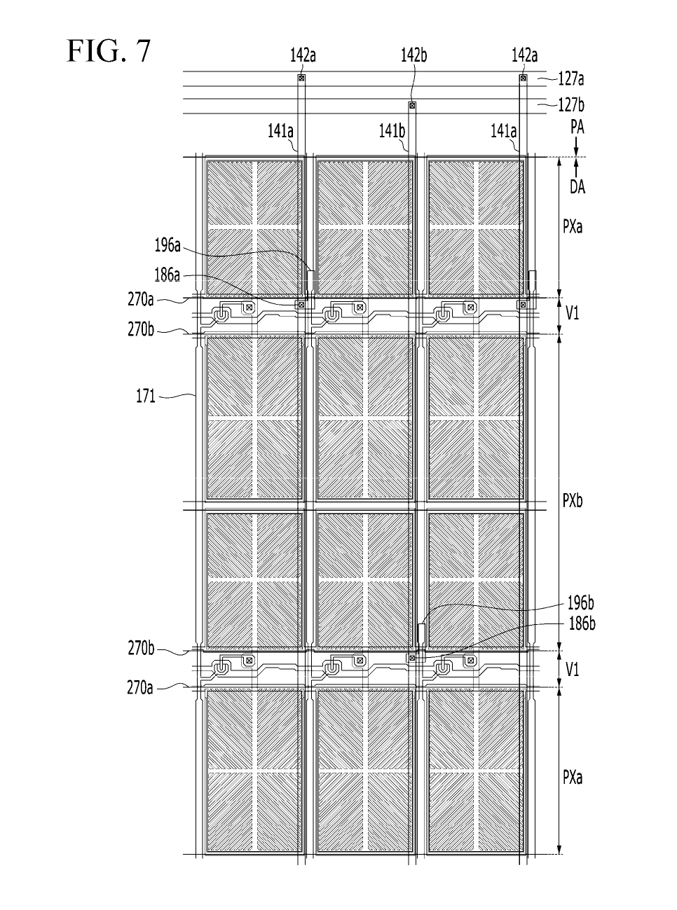

FIG. 6 is a schematic (top) plan view illustrating a pixel of a liquid crystal display according to an embodiment. FIG. 7 is a schematic (top) plan view illustrating a portion A indicated in FIG. 1 according to an embodiment. The liquid crystal display may have one or more features that are analogous to and/or identical to one or more features discussed above with reference to FIG. 1 to FIG. 5.

Referring to FIG. 6 and FIG. 7, in the liquid crystal display, each pixel column includes a first auxiliary common electrode line 141a or a second auxiliary common electrode line 141b per pixel. Pixel columns including first auxiliary common electrode lines 141a and pixel columns including second auxiliary common electrode lines 141b are alternately arranged along the pixel row direction.

Each first auxiliary common electrode line 141a and each second auxiliary common electrode line 141b is separated (and insulated) from data lines 171 and may extend substantially parallel to the data lines 171 in the pixel column direction. Each first auxiliary common electrode line 141a may be connected though a first bridge electrode 196a to a first common electrode 270a. First bridge electrodes 196a positioned in a same pixel row PXa may be electrically connected to a same first common electrode 270a and may be respectively electrically connected to different first auxiliary common electrode lines 141a. First bridge electrodes 196a may contact and connect to first auxiliary common electrode lines 141a through second contact holes 186a.

Each second auxiliary common electrode line 141b may be connected through a second bridge electrode 196b to a second common electrode 270b. Second bridge electrodes 196b positioned in a same pixel row PXb may be electrically connected to a same second common electrode 270b and may be respectively electrically connected to different second auxiliary common electrode lines 141b. Second bridge electrodes 196b may contact and connect to second auxiliary common electrode lines 141b through third contact holes 186b.

In an embodiment, first common electrodes 270a positioned at first pixel rows PXa may receive a first common voltage from first auxiliary common electrode lines 141a, and second common electrodes 270b positioned at second pixel rows PXb may receive a second common voltage from second auxiliary common electrode lines 141b, wherein the second common voltage may be unequal to the first common voltage. Therefore, an electric field formed in a first pixel area corresponding to a first common electrode 270a may be unequal to an electric field formed in a second pixel area corresponding to a second common electrode 270b. Advantageously, visibility of a displayed image may be optimized.

Various embodiments may involve various arrangements and/or various connection relationships of first auxiliary common electrode lines 141a, first common electrodes 270a, second auxiliary common electrode lines 141b, and/or second common electrodes 270b. In an embodiment, a first auxiliary common electrode line 141a, a second auxiliary common electrode line 141b, a first bridge electrode 196a, and a second bridge electrode 196b may be formed in one pixel; the connection between the first auxiliary common electrode line 141a and a first common electrode 270a and the connection between the second auxiliary common electrode line 141b and a second common electrode 270b may be implemented in this pixel. In an embodiment, the first auxiliary common electrode line 141a, the second auxiliary common electrode line 141b, the first bridge electrode 196a, and the second bridge electrode 196b may be positioned at a same side of the pixel.

In an embodiment, first common electrodes 270a and second common electrodes 270b may extend in the pixel column direction and may be alternately arranged along the pixel row direction; first auxiliary common electrode lines 141a may extend in the pixel column direction, may extend parallel to the first common electrodes 270a, and may respectively contact the first common electrodes 270a; second auxiliary common electrode lines 141b may extend in the pixel column direction, may extend parallel to the second common electrodes 270b, and may contact the second common electrode 270b. Therefore, pixel columns applied with the different voltages may be alternately arranged in the display area DA.

While some embodiments have been described as examples, possible embodiments are not limited to the disclosed embodiments. Embodiments are intended to cover various modifications and equivalent arrangements within the spirit and scope of the appended claims.

What is claimed is:

1. A liquid crystal display comprising:
a substrate including a display area and a non-display area;
a gate line extending in one direction on the substrate;
a first common electrode line and a second common electrode line positioned in the non-display area and formed in a direction that the gate line extends;
a data line crossing the gate line;
a first auxiliary common electrode line formed in a direction that the data line extends and connected to the first common electrode line;
a second auxiliary common electrode line formed along a direction that the data line extends and connected to the second common electrode line;
a first common electrode connected to the first auxiliary common electrode line; and
a second common electrode connected to the second auxiliary common electrode line.

2. The liquid crystal display of claim 1, wherein the first common electrode line and the second common electrode line are applied with different voltages.

3. The liquid crystal display of claim 2, further comprising:
a pixel electrode positioned on the first auxiliary common electrode line and the second auxiliary common electrode line;
a common electrode forming a microcavity with the pixel electrode and including a first common electrode and a second common electrode; and
a roof layer positioned on the common electrode.

4. The liquid crystal display of claim 3, wherein
the first auxiliary common electrode line and the second auxiliary common electrode line are formed of the same material as the data line.

5. The liquid crystal display of claim 4, wherein
the first common electrode and the second common electrode are respectively extended in a row direction and are alternately disposed in the row.

6. The liquid crystal display of claim 5, wherein
the display area includes a plurality of pixel areas, and
the first auxiliary common electrode line and the second auxiliary common electrode line are both formed in every pixel area.

7. The liquid crystal display of claim 6, wherein
the first auxiliary common electrode line and the first common electrode are connected through a first bridge electrode formed of the same material as the pixel electrode, and
the second auxiliary common electrode line and the second common electrode are connected through a second bridge electrode formed of the same material as the pixel electrode.

8. The liquid crystal display of claim 4, wherein
the display area includes a plurality of pixel areas, and
one of the first auxiliary common electrode line or the second auxiliary common electrode line is formed in every pixel area.

9. The liquid crystal display of claim 8, wherein
the first common electrode and the second common electrode are respectively formed in the row direction, and are alternately disposed in each row.

10. The liquid crystal display of claim 9, wherein
the first auxiliary common electrode line and the first common electrode are connected through a first bridge electrode formed of the same material as the pixel electrode, and
the second auxiliary common electrode line and the second common electrode are connected through a second bridge electrode formed of the same material as the pixel electrode.

11. A method for manufacturing a liquid crystal display, comprising:
forming a gate line, a first common electrode line, and a second common electrode line on a substrate in one direction;
forming a semiconductor layer on the substrate;
forming a data line crossing the gate line, a first auxiliary common electrode line parallel to the data line and connected to the first common electrode line, and a second auxiliary common electrode line connected to the second common electrode line on the substrate;
forming an insulating layer on the gate line, the first common electrode line, the second common electrode line, the semiconductor layer, the first auxiliary common electrode line, the second auxiliary common electrode line, and the data line;
forming a pixel electrode on the insulating layer;
forming a sacrificial layer on the pixel electrode;
forming a first common electrode and a second common electrode on the sacrificial layer;
forming a roof layer on the common electrode;
removing the sacrificial layer to form a microcavity including an injection hole;
injecting a liquid crystal material into the microcavity; and
forming an overcoat covering the injection hole on the roof layer.

12. The method of claim 11, wherein,
in the step of forming the first common electrode and the second common electrode, the first common electrode and the second common electrode are alternately formed in the row direction.

13. The method of claim 12, further comprising:
forming a first bridge electrode connected to the first auxiliary common electrode line and a second bridge electrode connected to the second auxiliary common electrode line while forming the pixel electrode; and
in the step forming the first common electrode and the second common electrode, the first common electrode is connected to the first auxiliary common electrode line through the first bridge electrode and the second common electrode is connected to the second auxiliary common electrode line through the second bridge electrode.

14. A display device comprising:
a switching element comprising a source electrode, a drain electrode, and a gate electrode;
a data line electrically connected to the source electrode;
a first pixel electrode electrically connected to the drain electrode;
a second pixel electrode immediately neighboring the first pixel electrode;
a first common electrode and a second common electrode respectively overlapping the first pixel electrode and the second pixel electrode;
a first auxiliary common electrode line and a second auxiliary common electrode line each extending parallel to the data line; and
a first common electrode line and a second common electrode line respectively electrically connected through the first auxiliary common electrode line and the second auxiliary common electrode line to the first common electrode and the second common electrode.

15. The display device of claim 14 further comprising:
a gate line electrically connected to the gate electrode and extending parallel to at least one of the first common electrode line and the second common electrode line.

16. The display device of claim 14 further comprising:
a gate line electrically connected to the gate electrode and formed of a same material as at least one of the first common electrode line and the second common electrode line.

17. The display device of claim 14, further comprising:
a first bridge electrode, wherein the first auxiliary common electrode line is electrically connected through the first bridge electrode to the first common electrode.

18. The display device of claim 17, wherein the first bridge electrode is formed of a same material as the first pixel electrode.

19. The display device of claim 17, wherein a first portion of the first bridge electrode directly contacts the first auxiliary common electrode line, and wherein a second portion of the first bridge electrode extends at an angle with respect to the first portion of the first bridge electrode in a plan view of the display device, overlaps the data line, and directly contacts the first common electrode.
